(19) United States
(12) Patent Application Publication
(10) Pub. No.: US 2013/0120015 A1
(43) Pub. Date: May 16, 2013

(54) TEST CARRIER

(71) Applicants: Kiyoto NAKAMURA, Miyagi (JP); Takashi FUJISAKI, Gunma (JP)

(72) Inventors: Kiyoto NAKAMURA, Miyagi (JP); Takashi FUJISAKI, Gunma (JP)

(21) Appl. No.: 13/677,653

(22) Filed: Nov. 15, 2012

(30) Foreign Application Priority Data
Nov. 16, 2011 (JP) 2011-250510

(51) Int. Cl. G01R 1/04

(52) U.S. Cl. CPC G01R 1/0491
USPC 324/756.02

(57) ABSTRACT

A test carrier which can suppress the occurrence of contact defects and secure positional precision of the terminals is provided.

The test carrier 10 comprises: a film-shaped base film 40 which has a plurality of bumps 43 which respectively contact electrode pads 91 of a die 90; and a cover film 70 which is laid over the base film 40 and which covers the die 90, and the plurality of bumps 43 include first bumps 43a and second bumps 43b which are relatively higher than the first bumps 43a.

### TECHNICAL FIELD

The present invention relates to a test carrier to which a die chip is temporarily mounted for testing an integrated circuit or other electronic circuit which is formed in the die chip.

The present application claims priority based on Japanese Patent Application No. 2011-250510 of a Japanese patent application which was filed on Nov. 16, 2011. The content which was described in that application is incorporated into the present application by reference and forms part of the description of the present application.

### BACKGROUND ART

Known in the art is a test carrier which comprises a contact sheet having a film made of a polyimide on which contact pads and interconnect patterns are formed. The contact pads correspond to electrode patterns of a chip under test, and the interconnect patterns are connected to the contact pads for contact with an external test apparatus (for example, see PLT 1).

### CITATION LIST

### Patent Literature

PLT 1: Japanese Patent Publication No. 7-263504 A1

### SUMMARY OF INVENTION

### Technical Problem

In the above test carrier, if the film of the contact sheet is too thick, since the film is high in rigidity, the film ends up riding over the edge of the chip whereby there are the problems that the electrode patterns which are positioned near the edge and the contact pads are not electrically connected and contact defects occur.

On the other hand, if the film of the contact sheet is too thin, the problems that elongation of the base film itself or waviness of the file due to stress at the time of forming the interconnects cause a drop in the positional precision of the contact pads.

The technical problem of the present invention is to provide a test carrier which can suppress the occurrence of contact defects and secure positional precision of the terminals.

### Solution to Problem

[1] A test carrier according to the present invention comprises: a film-shaped first member which has a plurality of terminals which respectively contact electrodes of an electronic device; and a second member which is laid over the first member and which covers the electronic device, and the plurality of terminals include: at least one first terminal; and at least one second terminal which is relatively higher than the first terminal.

[2] In the above invention, the second terminal may be arranged nearer to an outer circumferential edge of the electronic device than the first terminal.

[3] Further, the test carrier according to the present invention comprises: a film-shaped first member which has a first main surface has terminals which contact electrodes of an electronic device; and a second member which is laid over the first member and which covers the electronic device, and the first member is partially thick on the first main surface side.

[4] In the above invention, the first member may have: at least one first region; and at least one second region which is relatively thicker than the first region, and the second region may correspond to at least the electrode which is positioned near the outer circumferential edge of the electronic device.

[5] In the above invention, the electronic device may be a die which is diced from a semiconductor wafer.

[6] In the above invention, a holding space which is formed between the first member and the second member and which holds the electronic device may be reduced in pressure compared with the outside air.

### Advantageous Effects of Invention

In the present invention, the test carrier has the second terminal which is relatively higher than the first terminal, so even if not making the first member thin, it is possible to make the terminal contacts the electrode which is positioned near the edge of the electronic device and possible to suppress the occurrence of contact defects and secure positional precision of the terminals.

Further, in the present invention, the first main surface side of the first member is partially thick, so even if not making the first member as a whole thin, it is possible to make the terminals contact the electrodes which are positioned near the edge of the electronic device and possible to suppress the occurrence of contact defects and secure positional precision of the terminals.

### BRIEF DESCRIPTION OF DRAWINGS

FIG. 1 is a flow chart which shows a part of a process of production of a device in an embodiment of the present invention.

FIG. 2 is a disassembled perspective view of a test carrier in an embodiment of the present invention.

FIG. 3 is a cross-sectional view of a test carrier in an embodiment of the present invention.

FIG. 4 is a disassembled cross-sectional view of a test carrier in an embodiment of the present invention.

FIG. 5 is an enlarged view of a part V of FIG. 4.

FIG. 6 is a view along the arrow (side view) which shows bumps on a base film and a die from the direction A of FIG. 5.

FIG. 7 is a side view which shows a modification of the base film in an embodiment of the present invention.

FIG. 8 is a disassembled cross-sectional view which shows a first modification of a test carrier in an embodiment of the present invention.

FIG. 9 is a disassembled cross-sectional view which shows a second modification of a test carrier in an embodiment of the present invention.

FIG. 10(a) is an enlarged view of a part X of FIG. 3, while FIG. 10(b) is an enlarged view of a conventional test carrier.

### DESCRIPTION OF EMBODIMENTS

Below, an embodiment of the present invention will be explained based on the drawings.

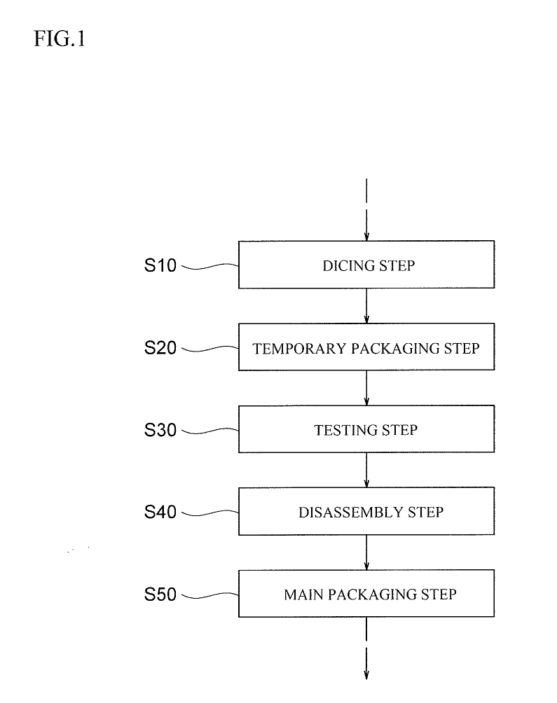

FIG. 1 is a flow chart which shows a part of a process of production of a device in the present embodiment.

In the present embodiment, after a semiconductor wafer is diced (after FIG. 1, step S10) and before final packaging (before step S50), the electronic circuits which are built into the die 90 are tested (steps S20 to S40).

In the present embodiment, first, a carrier assembly device (not shown) is used to temporarily mount a die 90 to a test carrier 10 (step S20). Next, through this test carrier 10, the die 90 and the test system (not shown) are electrically connected so as to test the electronic circuits which are built into the die 90 (step S30). Further, after this test ends, the die 90 is taken out from the test carrier 10 (step S40), then this die 90 is packaged by main packaging to thereby complete the device as a final product (step S50).

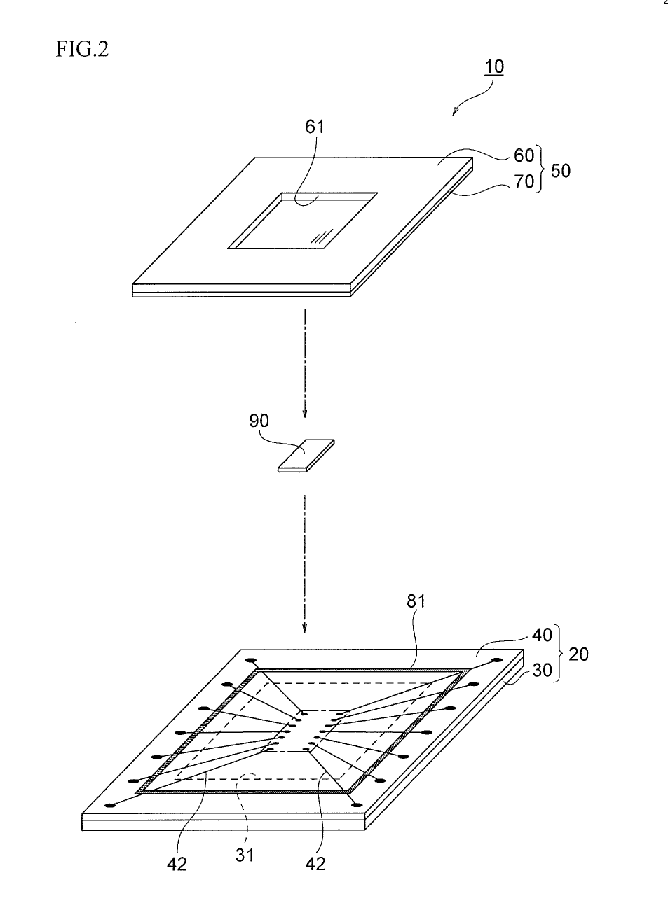

Below, the configuration of the test carrier 10 to which the die 90 is temporarily mounted (provisionally packaged) in the present embodiment will be explained while referring to FIG. 2 to FIG. 10.

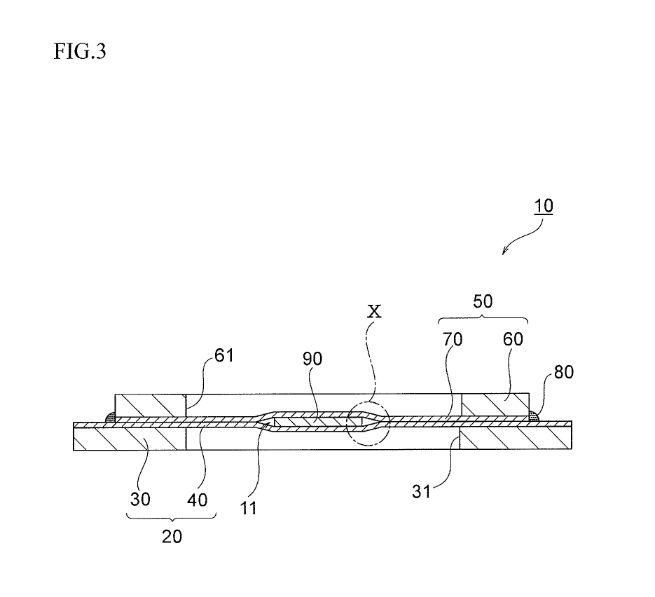

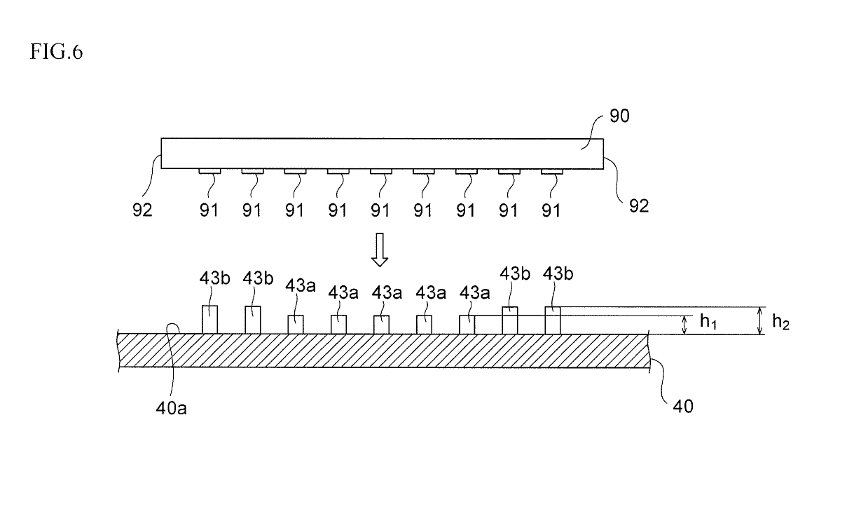

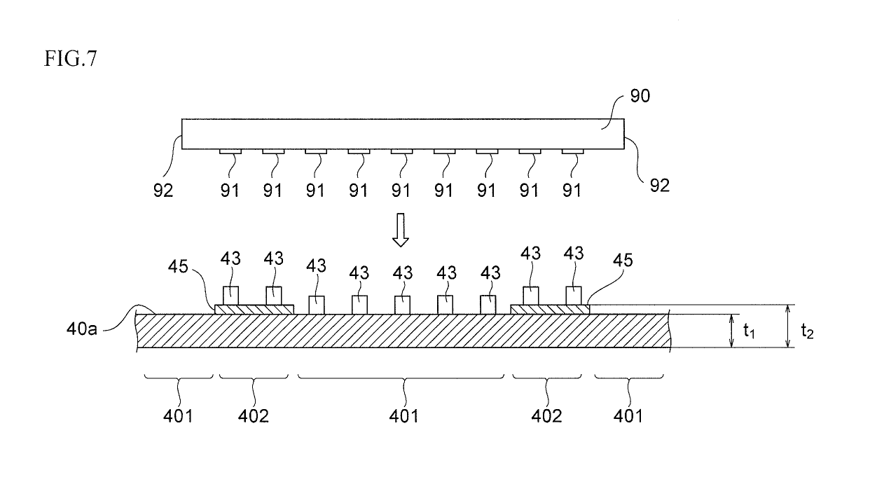

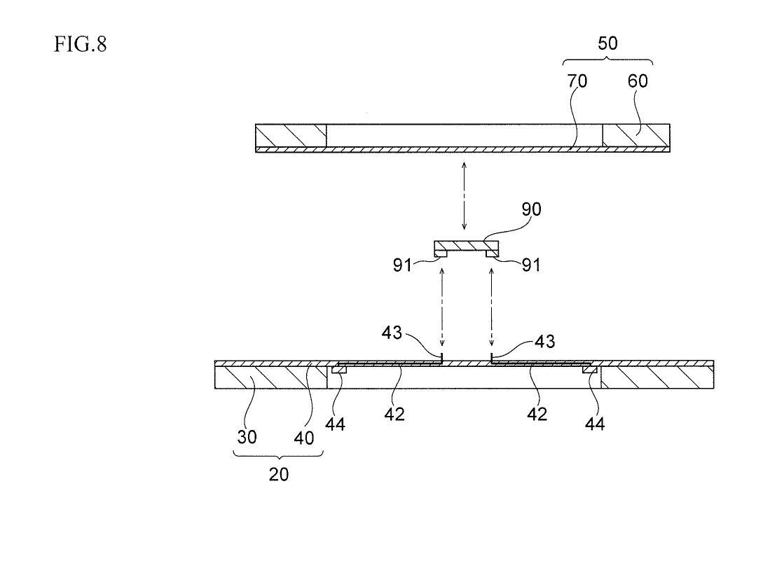

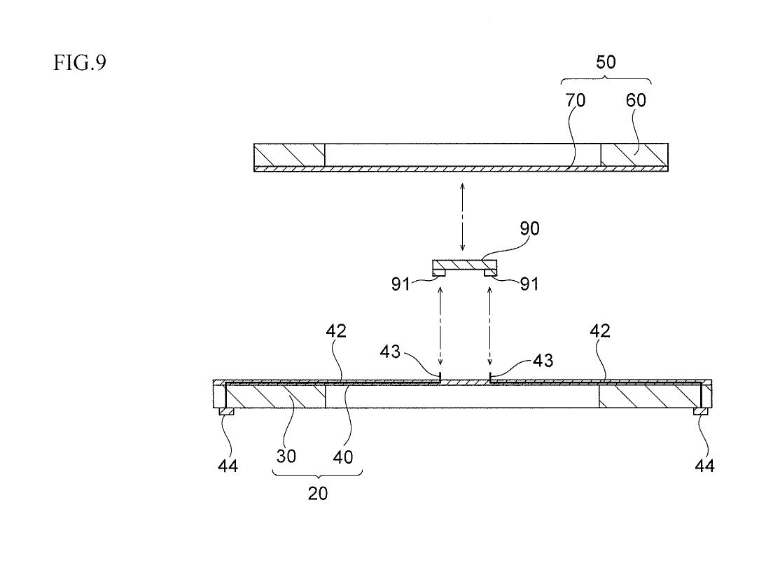

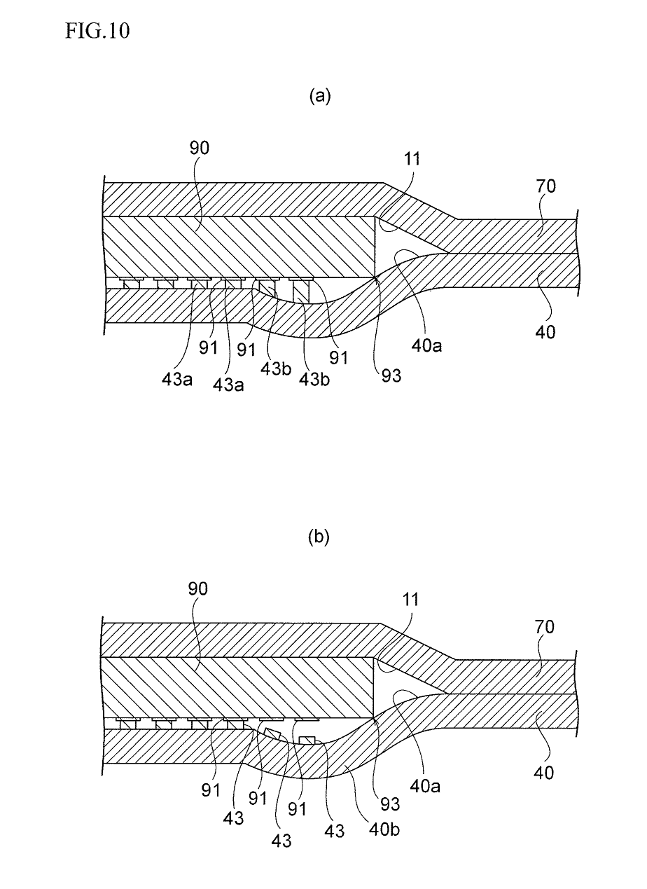

FIG. 2 to FIG. 5 are views which show a test carrier in which a die is temporarily mounted, FIG. 6 is a view which shows a relationship of bump height, FIG. 7 is a view which shows a modification of a base film, FIG. 8 and FIG. 9 are views which show modifications of the test carrier, FIG. 10(a) is an enlarged view of a part X of FIG. 3, and FIG. 10(b) is an enlarged view of a conventional test carrier.

The test carrier 10 in the present embodiment, as shown in FIG. 2 to FIG. 4, comprises: a base member 20 on which a die 90 is carried; and a cover member 50 which is laid on the base member 20 and which covers the die 90. This test carrier 10 sandwiches the die 90 between the base member 20 and the cover member 50 in a state reduced in pressure from atmospheric pressure to thereby hold the die 90.

The base member 20 comprises a base frame 30 and a base film 40. The base film 40 in the present embodiment is equivalent to one example of the first member in the present invention.

The base frame 30 is a rigid board which has a high rigidity (at least a rigidity higher than the base film 40 or the cover film 70) and is formed with an opening 31 at the center. As the material which forms this base frame 30, for example, a polyamide imide resin, ceramic, glass, etc. may be illustrated.

On the other hand, the base film 40 is a film which has flexibility and is attached to the entire surface of the base frame 30, including the center opening 31, through a binder (not shown). In this way, in the present embodiment, since the base film 40 which has flexibility is attached to the base frame 30 which has a high rigidity, the handling ability of the base member 20 is improved.

Note that, it is also possible to omit the base frame 30 and configure the base member 20 by only the base film 40. Alternatively, it is also possible to omits the base film 40 and use a rigid printed circuit board as the base member 20, the rigid printed circuit board is the base frame on which the interconnect patterns 42 is formed and which does not have the opening 31.

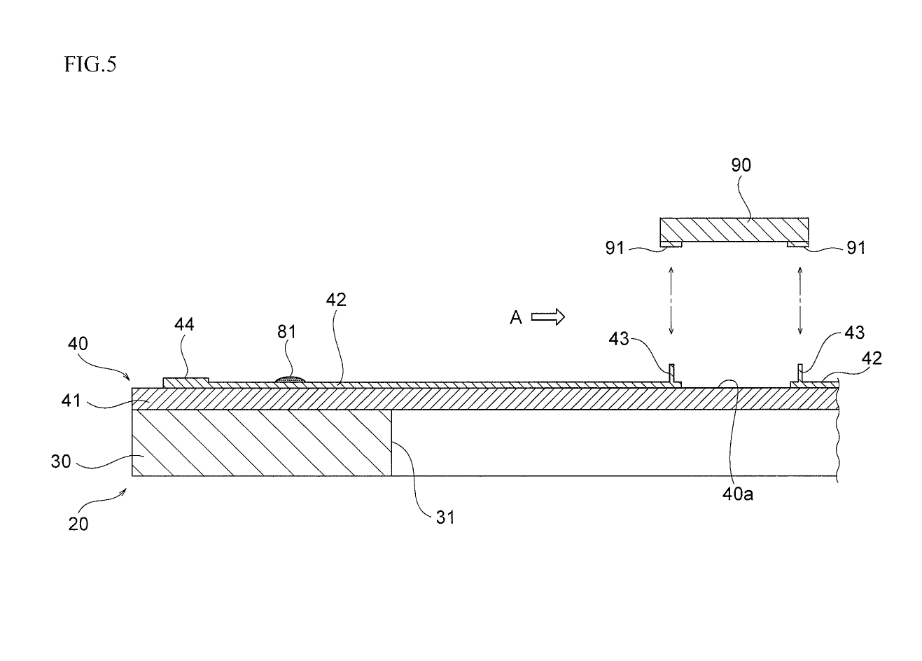

As shown in FIG. 5, this base film 40 has a film body 41 and interconnect patterns 42 which are formed on the surface of the film body 41. The film body 41, for example, comprises polyimide film etc. Further, the interconnect patterns 42 are, for example, formed by etching copper film which is laminated on the film body 41.

Note that, the film body 41 may be laminated with a cover layer which for example comprises a polyimide film so as to protect the interconnect patterns 42 or a so-called multilayer flexible printed circuit board may be used as the base film 40. Further, part of the interconnect patterns 42 may be formed on the surface of the base film 40 by ink jet printing in real time. Alternatively, all of the interconnect patterns 42 may be formed by ink jet printing.

As shown in FIG. 5, a bump 43 which electrically contacts an electrode pad 91 of the die 90 is provided at one end of each interconnect pattern 42. The bump 43 is, for example, composed of copper (Cu), nickel (Ni), etc. and, for example, is formed by the semiadditive method on the end of the interconnect pattern 42. Such bumps 43 are arranged so as to correspond to the electrode pads 91 of the die 90. The die 90 in the present embodiment is equivalent to one example of an electronic device in the present invention, the electrode pad 91 in the present embodiment is equivalent to one example of the electrode in the present invention, and the bump 43 in the present embodiment is equivalent to one example of the terminal in the present invention.

In the present embodiment, as shown in FIG. 6, as the bumps 43, there are two types, that is, the first bumps 43a and the second bumps 43b. One end of each of the plurality of interconnect patterns 42 is provided with either a first bump 43a or a second bump 43b.

The first bumps 43a have a predetermined first height h₁. As opposed to this, the second bumps 43b have a second height h₂ which is relatively higher than the first height h₁ (h₂>h₁). The second bumps 43b are arranged, in the side view which is shown in FIG. 6, closer to the outer circumferential edge 92 of the die 90 than the first bumps 43a. Note that, the number of the second bumps 43b is not particularly limited. When reducing the pressure and sealing the die 90 between the base member 20 and the cover member 50, it is sufficient that the second bumps 43b are positioned at the raised up part 40b of the base film 40 (see FIG. 10(a)).

As the method for making the second bumps 43b higher than the first bumps 43a, for example, the method of increasing the number of times the second bumps 43b are plated compared with the first bumps 43a may be illustrated. Alternatively, the first bumps 43a and the second bumps 43b may be separately plated so as to make the second bumps 43b relatively higher than the first bumps 43a, or just the first bumps 43a may be ground down so as to make the second bumps 43b relatively higher than the first bumps 43a.

Note that, instead of making the heights of the bumps themselves different, as shown in FIG. 7, the inside main surface 401 of the base film 40 may also be partially thicker. Specifically, the base film 40 includes: first regions 401 which have a first thickness t₁; and second regions 402 which have a second thickness t₂ (t₂>t₁) which is relatively thicker than the first thickness t₁. The second regions 402 correspond to the electrode pads 91 which are positioned near the outer circumferential edge 92 of the die 90 in the side view. The inside main surface 401 of the base film 40 in the present embodiment is equivalent to one example of the first main surface of the first member in the present invention. Note that, in the present example, all of the bumps 43 which are provided on the base film 40 have substantially the same height.

As the method of making the base film 401 partially thicker, for example, the method of partially laminating an additional layer 45 which is composed of a polyimide etc. through a binder etc. on the inside surface 401 of the base film 40 may be illustrated. Note that, the method of making the base film 40 partially thicker is not particularly limited. For example, it is also possible to make only the first regions 401 thinner in the base film by wet etching etc. to thereby make the second regions 402 relatively thicker than the first regions 401.

Returning to FIG. 5, an external terminal 44 is formed at the other end of the interconnect pattern 42. At the time of the test of the electronic circuits which are built into the die, these external terminals 44 are electrically contacted by contactors of the test system (not shown) whereby the die 90 is electrically connected through the test carrier 10 to the test system.

Note that, the positions of the external terminals 44 are not limited to the above positions. For example, as shown in FIG. 8, the external terminals 44 may also be formed on the bottom surface of the base film 40. Alternatively, as shown in FIG. 9, the external terminals 44 may be formed on the bottom surface of the base frame 30. In the example which is shown in FIG. 9, the base frame 30 is formed with through holes and interconnect patterns so as to electrically connect the interconnect patterns 42 and the external terminals 44.

Further, while not particularly shown, in addition to the base film 40, the cover film 70 may be formed with the interconnect patterns 42 or external terminals 44, and the cover frame 60 may be formed with the external terminals 44.

Returning to FIG. 2 to FIG. 4, the cover member 50 comprises a cover frame 60 and a cover film 70. The cover film 70 in the present embodiment is equivalent to one example of the second member in the present invention.

The cover frame 60 is a rigid board which has a high rigidity (at least a rigidity higher than the base film 40 or cover film 70) and which is formed with an opening 61 at its center. In the present embodiment, this cover frame 60, like the above-mentioned base frame 30, is composed of a polyimide resin, ceramic, glass, etc.

On the other hand, the cover film 70 is a film which has flexibility and, for example, in the same way as the film body 41 of the above-mentioned base film 40, comprises a polyimide film etc. This cover film 70 is adhered to the entire surface of the cover frame 60, including the center opening 61, by a binder (not shown). In the present embodiment, a flexible cover film 70 is adhered to the high rigidity cover frame 60, so an improvement in the handling ability of the cover member 50 is achieved.

Note that, the cover member 50 may also comprise only the cover film 70. Alternatively, when the base member 20 has the base film 40, the cover member 50 may comprise only the rigid board not formed with the opening 61.

The above explained test carrier 10 is assembled as explained below.

First, in the state where the electrode pads 91 are aligned with the bumps 43, the die 90 is placed on the base film 40 of the base member 20.

Next, in an environment which is reduced in pressure compared with atmospheric pressure, the cover member 50 is laid over the base member 20 to sandwich the die 90 between the base member 20 and the cover member 50. At this time, the base film 40 and the cover film 70 are made to directly contact by laying the cover member 50 over the base member 20.

Incidentally, when the die 90 is relatively thick, while not particularly shown, the base frame 30 and the cover frame 60 may be made to directly contact by laying the cover member 50 over the base member 20.

Next, in the state with the die 90 sandwiched between the base member 20 and the cover member 50, the test carrier 10 is returned to an atmospheric pressure environment whereby the die 90 is held inside the holding space 11 (see FIG. 3) which is formed between the base member 20 and the cover member 50.

Here, as shown in FIG. 10(b), when the plurality of bumps 43 are not partially higher, the base film 40 rides over the edge 93 of the die 90, part of the bumps 43 end up rising from the electrode pads 91, the electrode pads 91 which are positioned near the edges 93 of the die 90 do not electrically connect with the bumps 43, and therefore contact defects occur.

On the other hand, while not particularly shown, if the base film is too thin in thickness, elongation of the base film itself or waviness of the base film due to stress at the time of forming the interconnects cause a drop in the positional precision of the bumps.

As opposed to this, in the present embodiment, as shown in FIG. 10(a), even if the base film 40 rides over the edge 93 of the die 90 due to securing a predetermined rigidity of the base film 40, the high second bumps 44b which are formed on the raised up part 40b of the base film 40 contact the electrode pads 91 which are positioned near the edge 93 of the die 90, so occurrence of contact defects can be suppressed.

Incidentally, the electrode pads 91 of the die 90 and the bumps 43 of the base film 40 are not fastened by solder etc. In the present embodiment, the holding space 11 becomes a negative pressure compared with atmospheric pressure, so the die 90 is pushed by the base film 40 and the cover film 70, and the electrode pads 91 of the die 90 and the bumps 43 of the base film 40 contact each other.

Note that, as shown in FIG. 3, the base member 20 and the cover member 50 may also be fastened together by a bonded part 80 so as to prevent positional deviation and improve the air-tightness. As the binder 81 which forms this bonded part 80, for example, a UV curing type binder may be illustrated.

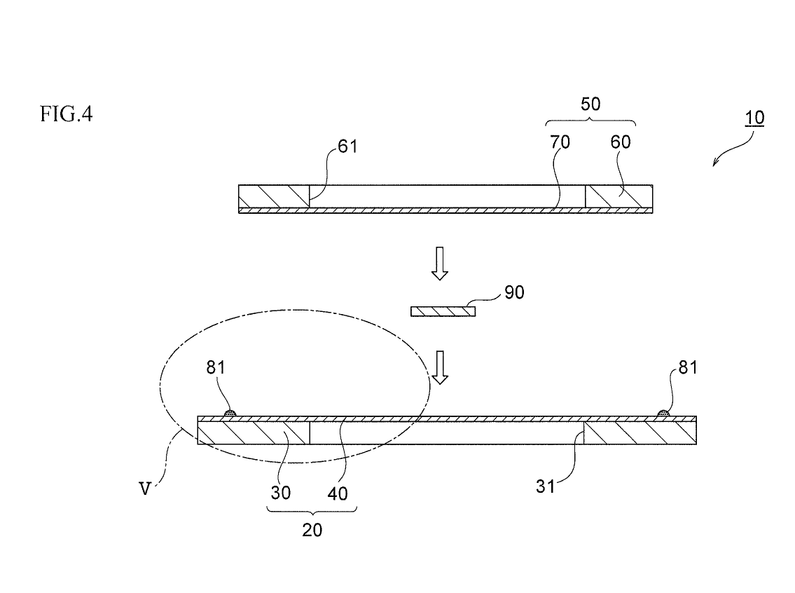

This binder 81, as shown in FIG. 2, FIG. 4, and FIG. 5, is applied on the base member 20 at positions corresponding to the outer circumference of the cover member. By placing the cover member 50 on the base member 20, then firing UV rays to cure the binder 81, the bonded part 80 is formed.

The above assembled test carrier 10 is transported to a not particularly shown test system where, in step S30 of FIG. 1, the contactors of the test system electrically contact the external terminals 44 of the test carrier 10, the test system and the electronic circuits of the die 90 are electrically connected through the test carrier 10, and the electronic circuits are tested.

Note that, when bonding the base member 20 and the cover member 50 by the bonded part 80, then pushing the test carrier 10 from the outside at the time of the test so as to make the electrode pads 91 of the die 90 and the bumps 43 contact, the holding space 11 need not be reduced in pressure.

In the above way, in the present embodiment, the test carrier has second bumps 43b which are relatively higher than the first bumps 43a, so even if not making the base film 40 thinner, the bumps 43 can be made to contact the electrode pads 91 which are positioned near the edges 93 of the die 90, the occurrence of contact defects can be suppressed, and the positional precision of the bumps 43 can be secured.

Further, in the present embodiment, the inside main surface side 40a of the base film 40 is partially thicker, so even if making the base film 40 overall thinner, the bumps 43 can be made to contact the electrode pads 91 which are positioned near the edge 93 of the die 90, the occurrence of contact defects can be suppressed, and the positional precision of the bumps 43 can be secured.

Note that, the above explained embodiment was described to facilitate understanding of the present invention and was not described for limiting the present invention. Therefore, the elements which were disclosed in the embodiment include all design changes and equivalents falling under the technical scope of the present invention.

### REFERENCE SIGNS LIST

10 . . . test carrier
11 . . . holding space
20 . . . base member
30 . . . base frame
31 . . . center opening
40 . . . base film
40a . . . inside main surface
40b . . . raised up part
401 . . . first regions
402 . . . second regions
41 . . . film body
42 . . . interconnect pattern
43 . . . bump
43a . . . first bump
43b . . . second bump
44 . . . external terminal
45 . . . additional layer
50 . . . cover member
60 . . . cover frame
61 . . . center opening
70 . . . cover film
80 . . . bonded part
81 . . . binder
90 . . . die
91 . . . electrode pad
92 . . . outer circumferential edge
93 . . . edge

1. A test carrier comprising:
a film-shaped first member which has a plurality of terminals which respectively contact electrodes of an electronic device; and
a second member which is laid over the first member and which covers the electronic device, wherein
the plurality of terminals include:
at least one first terminal; and
at least one second terminal which is relatively higher than the first terminal.

2. The test carrier as set forth in claim 1, wherein the second terminal is arranged nearer to an outer circumferential edge of the electronic device than the first terminal.

3. A test carrier comprising:
a film-shaped first member which has a first main surface has terminals which contact electrodes of an electronic device; and
a second member which is laid over the first member and which covers the electronic device, wherein
the first member is partially thick on the first main surface side.

4. The test carrier as set forth in claim 3, wherein
the first member has:
at least one first region; and
at least one second region which is relatively thicker than the first region, and
the second region corresponds to at least the electrode which is positioned near the outer circumferential edge of the electronic device.

5. The test carrier as set forth in claim 1, wherein the electronic device is a die which is diced from a semiconductor wafer.

6. The test carrier as set forth in claim 1, wherein a holding space which is formed between the first member and the second member and which holds the electronic device is reduced in pressure compared with the outside air.

7. The test carrier as set forth in claim 3, wherein the electronic device is a die which is diced from a semiconductor wafer.

8. The test carrier as set forth in claim 3, wherein a holding space which is formed between the first member and the second member and which holds the electronic device is reduced in pressure compared with the outside air.
